(19) United States
(12) Patent Application Publication
(10) Pub. No.: US 2014/0206169 A1
(43) Pub. Date: Jul. 24, 2014

(54) Methods of Fabricating Semiconductor Device Using Nitridation of Isolation Layers

(71) Applicant: SAMSUNG ELECTRONICS CO., LTD., Suwon-si (KR)

(72) Inventors: Ji Hoon Cha, Seoul (KR); Jae-Jik Baek, Seongnami-si (KR); Bo-Un Yoon, Seoul (KR); Young-Sang Youn, Suwon-si (KR); Jeong-Nam Han, Seoul (KR)

(73) Assignee: Samsung Electronics Co., Ltd., Suwon-si (KR)

(21) Appl. No.: 13/834,118

(22) Filed: Mar. 15, 2013

(30) Foreign Application Priority Data
Jan. 21, 2013 (KR) 10-2013-0006603

(51) Int. Cl. H01L 29/66

(52) U.S. Cl. CPC H01L 29/66477
USPC 438/294

(57) ABSTRACT

A method of forming a semiconductor device can include providing a plasma nitrided exposed top surface including an active region and an isolation region. The exposed top surface including the active region and the isolation region can be subjected to etching to form a deeper recess in the active region that in the isolation region and an unmerged epitaxial stress film can be grown in the deeper recess.

### CROSS-REFERENCE TO RELATED APPLICATION

This application claims priority from Korean Patent Application No. 10-2013-0006603 filed on Jan. 21, 2013 in the Korean Intellectual Property Office, and all the benefits accruing therefrom under 35 U.S.C. 119, the contents of which in its entirety are herein incorporated by reference.

### FIELD

The present inventive concept relates to a method for fabricating a semiconductor device.

### BACKGROUND

Various methods for improving a driving current of a transistor have been developed. Specifically, a method for improving a driving current by applying stress to a channel area of the transistor has been used.

In order to apply stress to a channel area of a transistor, an active region of a semiconductor substrate may be etched, followed by performing epitaxial growth, thereby forming a stress film for applying stress to the channel area. When the semiconductor substrate is etched, an isolation region may also be etched together with the active region.

### SUMMARY

According to an aspect of the present inventive concept, there is provided a method for fabricating a semiconductor device, the method including exposing an isolation region and an active region by patterning an etch stop layer formed on a substrate having the isolation region and the active region, nitridating a top surface of the exposed top surface of the isolation region by performing plasma nitridation, forming a first recess on the exposed active region, and forming a stress film in the first recess.

According to another aspect of the present inventive concept, there is provided a method for fabricating a semiconductor device, the method including providing a substrate having a first region and a second region isolated by an isolation region, forming an etch stop layer on the second region, nitridating a top surface of the isolation region and a top surface of the first region by performing plasma nitridation, forming a first recess in the first region, and forming a stress film in the first recess.

According to another aspect of the present inventive concept, a method of forming a semiconductor device can include providing a plasma nitrided exposed top surface including an active region and an isolation region. The exposed top surface including the active region and the isolation region can be subjected to etching to form a deeper recess in the active region than in the isolation region and an unmerged epitaxial stress film can be grown in the deeper recess.

### BRIEF DESCRIPTION OF THE DRAWINGS

The above and other features and advantages of the present inventive concept will become more apparent by describing in detail preferred embodiments thereof with reference to the attached drawings in which:

FIG. 1 is a flowchart illustrating a method for fabricating a semiconductor device according to an embodiment of the present inventive concept;

FIGS. 2 to 16 illustrate intermediate process steps for explaining a method for fabricating a semiconductor device according to an embodiment of the present inventive concept;

FIG. 17 illustrates effects demonstrated in a method for fabricating a semiconductor device according to an embodiment of the present inventive concept;

FIGS. 18 to 23 illustrate intermediate process steps for explaining a method for fabricating a semiconductor device according to another embodiment of the present inventive concept;

FIG. 24 is a flowchart illustrating a method for fabricating a semiconductor device according to still another embodiment of the present inventive concept;

FIGS. 25 to 34 illustrate intermediate process steps for explaining a method for fabricating a semiconductor device according to still another embodiment of the present inventive concept;

FIG. 35 is a block diagram of a memory card incorporating a semiconductor device fabricated by a fabricating method according to some embodiments of the present inventive concept.

FIG. 36 is a block diagram showing an information processing system using a semiconductor device fabricated by a fabricating method according to some exemplary embodiments of the present inventive concept; and

FIG. 37 is a block diagram of an electronic system including a semiconductor device according to some embodiments of the present inventive concept.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

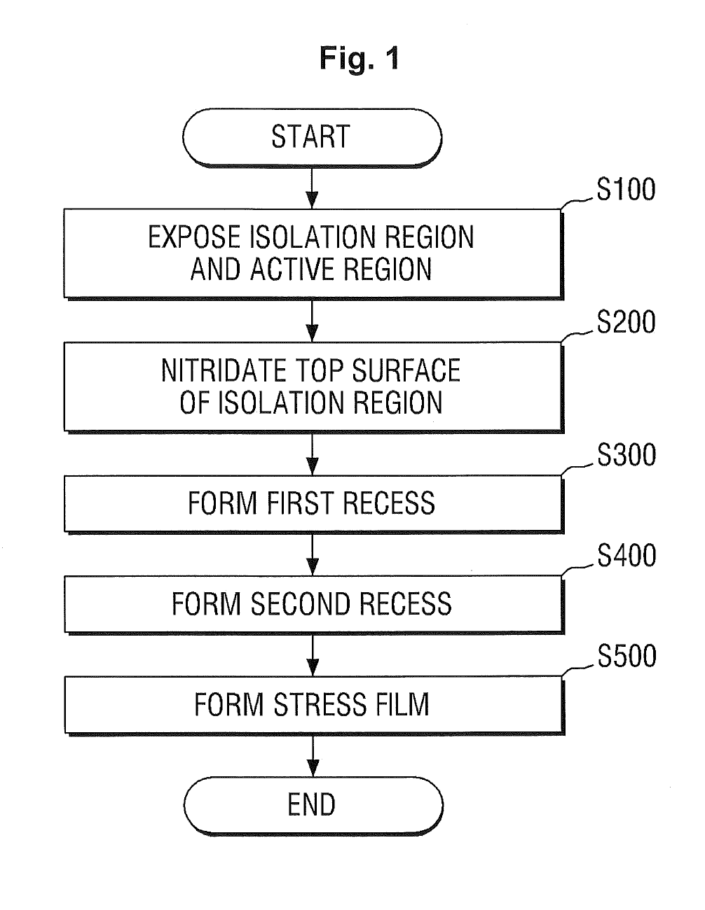

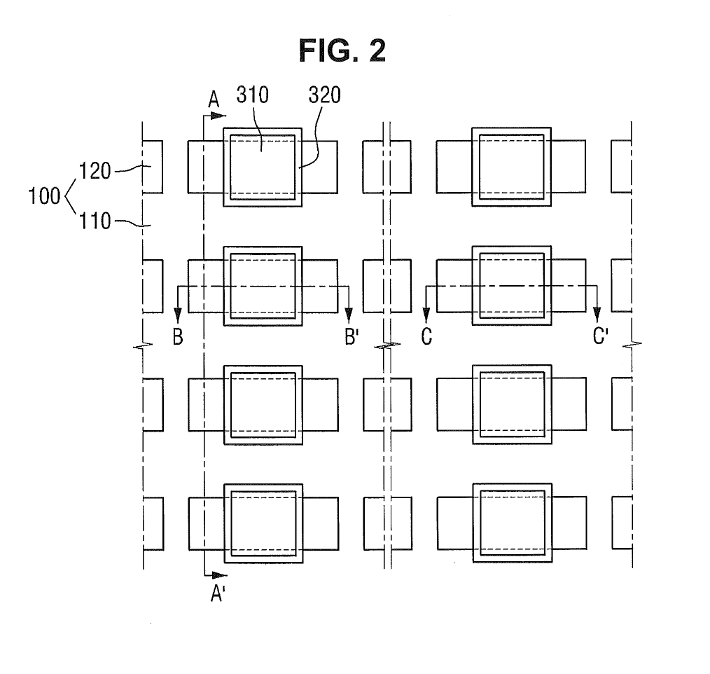

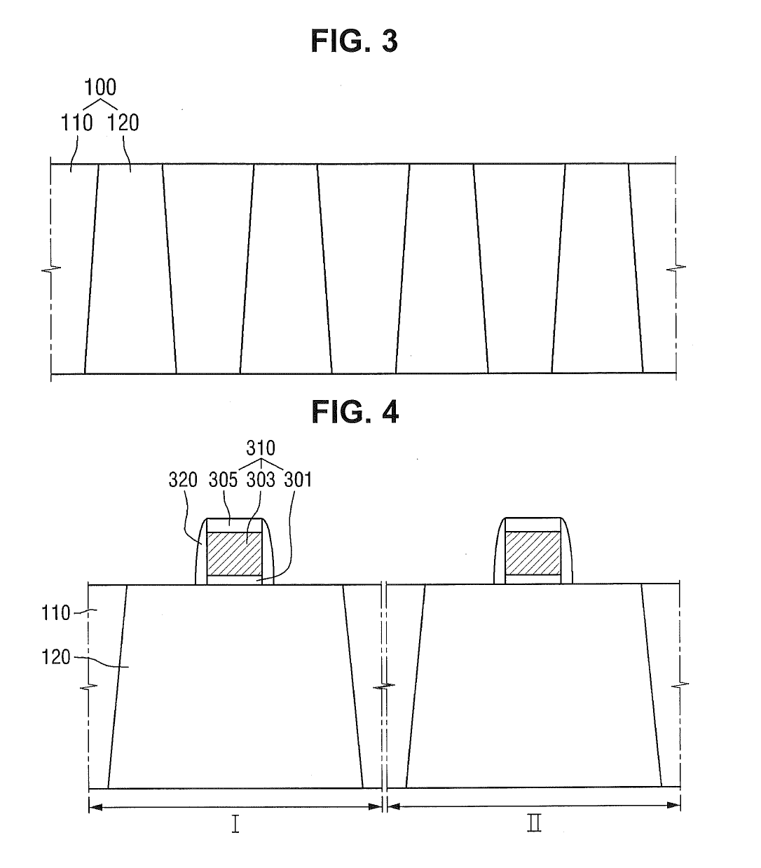

Hereinafter, a method for fabricating a semiconductor device according to an embodiment of the present inventive concept will be described with reference to FIGS. 1 to 16. FIG. 1 is a flowchart illustrating a method for fabricating a semiconductor device according to an embodiment of the present inventive concept, and FIGS. 2 to 16 illustrate intermediate process steps for explaining a method for fabricating a semiconductor device according to an embodiment of the present inventive concept. Specifically, FIG. 2 is a plan view of a semiconductor device according to an embodiment of the present inventive concept, FIGS. 3, 5, 7, 9, 11, 13, 15 and 17 are cross-sectional views taken along the line A-A′ of FIG. 2, and FIGS. 4, 6, 8, 10, 12, 14 and 16 are cross-sectional views taken along the line B-B of FIG. 2.

Referring first to FIG. 1, an etch stop layer formed on a substrate having an isolation region and an active region is patterned, thereby exposing the isolation region and the active region (S100).

Referring to FIGS. 2 and 3, the substrate 100 may include an isolation region 110, an active region 120 and a gate electrode structure 310.

The substrate 100 may be, for example, a semiconductor substrate such as a silicon wafer, a silicon-on-insulator (SOI) wafer, a gallium arsenic wafer, a silicon germanium wafer, or the like. The isolation region 110 may be, for example, a shallow trench isolation (STI) region. The STI region may be formed by forming a trench in the substrate 100 and then forming an insulation layer in the trench. The insulation layer may be, for example, a silicon oxide (SiO₂). The insulation layer may be formed by, for example, a chemical vapor deposition (CVD) process, but aspects of the present inventive concept are not limited thereto. The isolation region 110 may isolate the active regions 120 from one another. In addition, the isolation region 110 may isolate a first region (I of FIG. 4) and a second region (II of FIG. 4), which will later be described.

Referring to FIGS. 2 and 4, the active region 120 may include a first region I and a second region II. The first region I is a portion taken along the line B-B′ of FIG. 2, and the second region II is a portion taken along the line C-C′ of FIG. 2. The isolation region 110 may isolate the first region I and the second region II.

For clarity, the following description of embodiments will be described on the assumption that the first region I is a PMOS region and the second region II is an NMOS. However, the embodiments are not limited to their specified form as illustrated. For example, the first region I may be an NMOS region and the second region □ may be a PMOS region.

A gate electrode structure 310 may be formed on the active region 120. The gate electrode structure 310 may include a gate insulation layer 301, a gate electrode 303 and a gate mask 305 sequentially stacked. A gate spacer 320 is formed on lateral surfaces of the gate electrode structure 310 and protects the gate electrode structure 310.

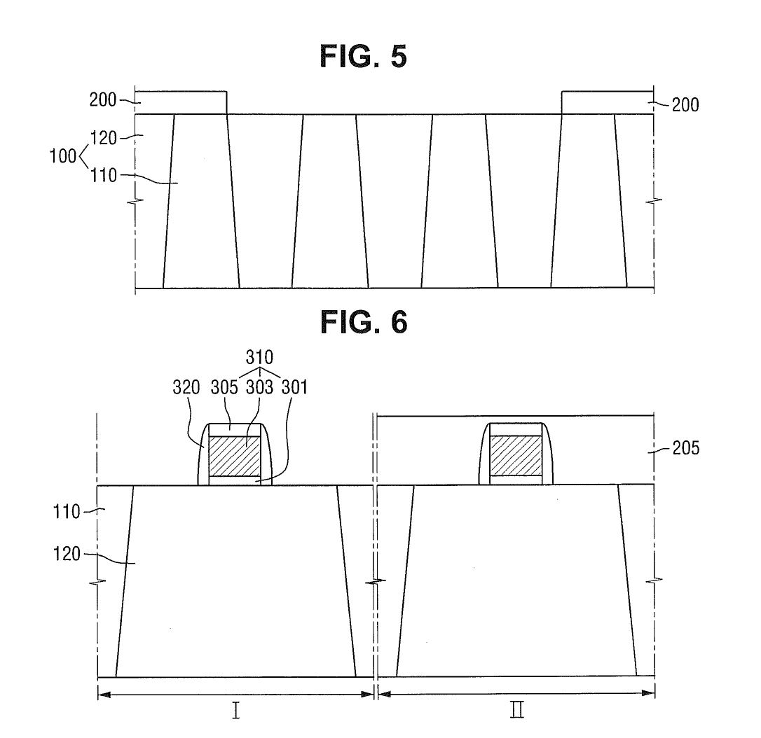

Referring to FIG. 5, an etch stop layer 200 is formed on the substrate 100. The etch stop layer 200 covers the substrate 100, excluding the active region 120 on which recesses are to be formed, and the isolation region 110 positioned between neighboring active regions 120. Therefore, once the etch stop layer 200 is formed, the isolation region 110 and the active region 120 underlying the etch stop layer 200 are not etched.

Referring to FIG. 6, the etch stop layer 205 is formed on the second region II but is not formed on the first region I, That is to say, if the etch stop layer 205 is formed on the second region II, a recess is not formed on the second region II.

For example, the etch stop layers 200 and 205 may be formed on the entire surface of the substrate 100 and then patterned to expose only the substrate 100 having the first region I. The patterning of the etch stop layers 200 and 205 may include, for example, a photolithography process.

Meanwhile, the etch stop layers 200 and 205 may include, for example, SiN, but aspects of the present inventive concept are not limited thereto.

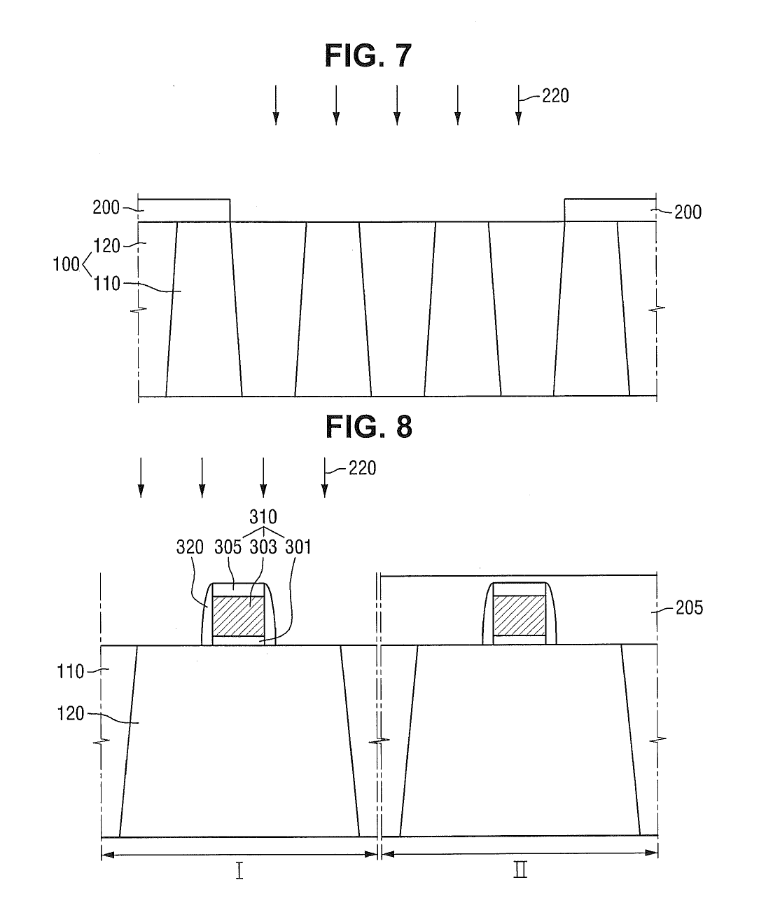

Next, referring again to FIG. 1, plasma nitridation is performed to nitridate a top surface of the exposed isolation region (S200). Referring to FIGS. 7 and 8, when the top surface of the isolation region 110 is nitridated, the active region 120, specifically, a top surface of the first region I of the active region 120 may also be nitridated, but aspects of the present inventive concept are not limited thereto. For example, only the top surface of the isolation region 110 may be nitridated.

In order to nitridate the top surface of the isolation region 110 and the top surface of the active region 120, plasma nitridation 220 may be used. The use of the plasma nitridation 220 allows the top surface of the isolation region 110 and the top surface of the active region 120 to be uniformly nitridated to a desired thickness.

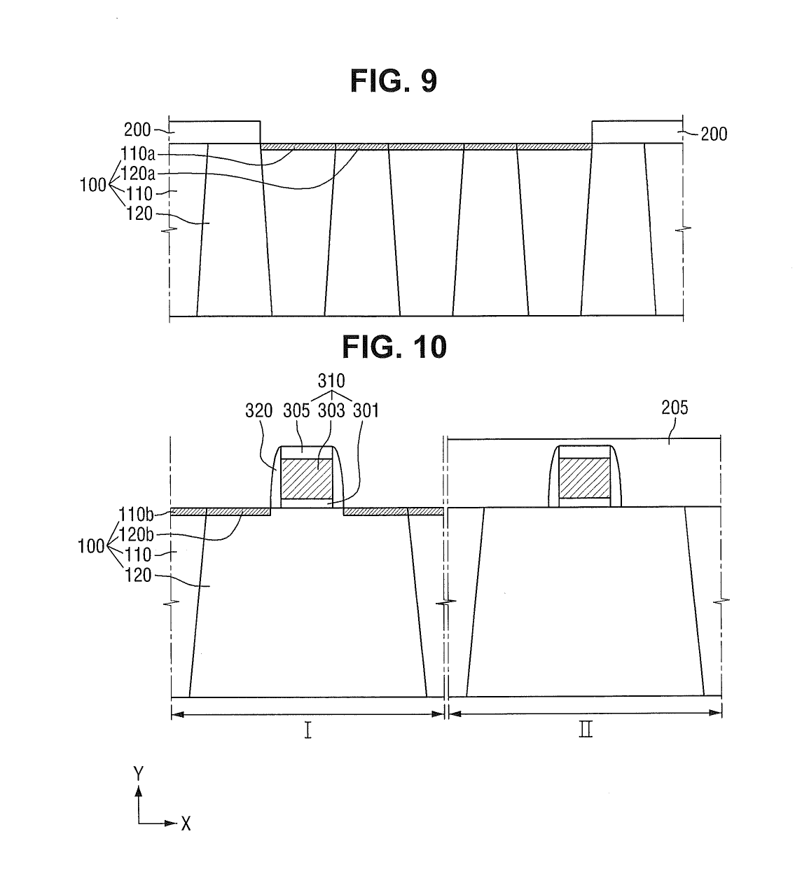

As the result of the plasma nitridation (220), as shown in FIGS. 9 and 10, nitridated isolation regions 110a and 110b are formed on the top surface of the isolation region 110, and nitridated active regions 120a and 120b are formed on the top surface of the active region 120, specifically, on the top surface of the first region I of the active region 120. Since the etch stop layer 205 exists on the second region II, the top surface of the second region I is not nitridated. The plasma nitridation 220 may be performed in one direction, for example, in the y-axis direction. Since nitridation is not performed in the x-axis direction, the first region I underlying the gate electrode structure 310 and the gate spacer 320 is not nitridated.

Next, referring again to FIG. 1, the first recess 130 is formed on the exposed active region 120 (S300).

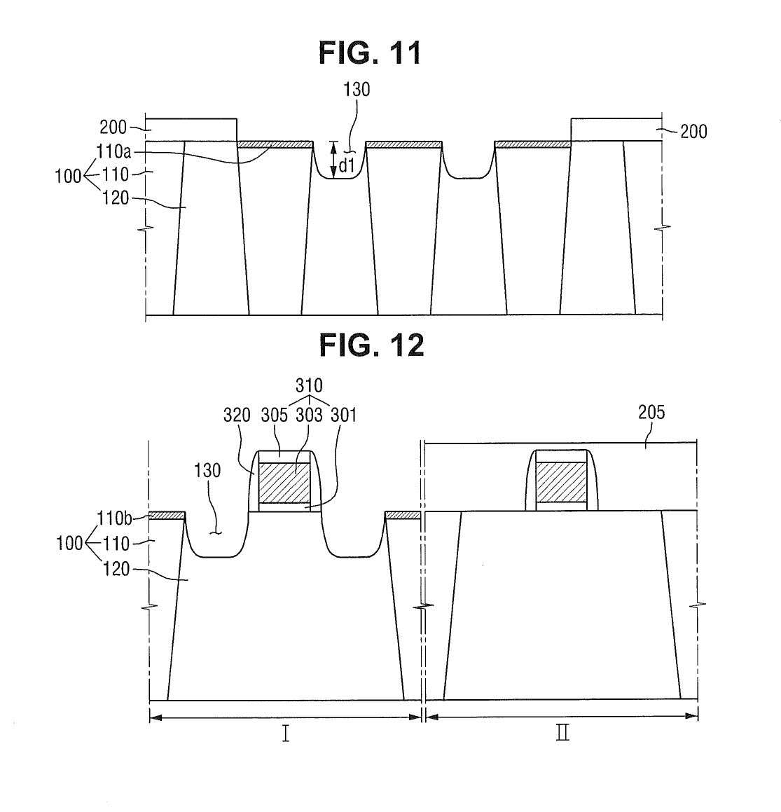

Referring to FIGS. 11 and 12, in order to form the first recess 130 on the active region 120, dry etching may be performed. In a case where the nitridated isolation regions 110a and 110b are dry etched, the etching amount of the top surfaces of the nitridated isolation regions 110a and 110b is reduced by 90% or greater, compared to a case where the top surface of the non-nitridated isolation region 110. For example, the amount of dry etching of the non-nitridated isolation region 110 is approximately 18 Angstroms while the amount of dry etching of the nitridated isolation regions 110a and 110b is 1.8 Angstroms or less. Therefore, the exposed isolation region 110 is not substantially etched, and the first recess 130 may be formed only on the active region 120, specifically only on the first region I of the active region 120. In the present inventive concept, if the etching amount is not 90% or greater, it is assumed that etching is not substantially performed.

For example, if the active region 120 includes Si, the nitridated active regions 120a and 120b may include SiN, which is the same as the material included in the etch stop layer 200. However, unlike the etch stop layer 200 having a large thickness, the nitridated active regions 120a and 120b formed by plasma nitridation have small thicknesses. Thus, even if the nitridated active regions 120a and 120b include SiN, they may be removed, thereby forming the first recess 130 in the active region 120.

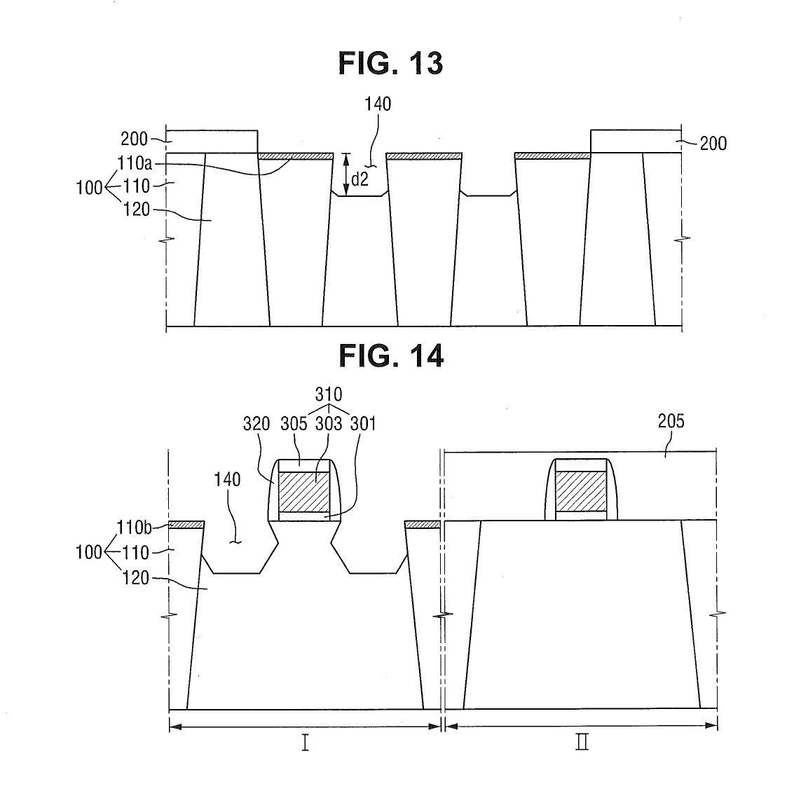

Next, referring again to FIG. 1, a second recess 140 is formed in the first recess 130 (S400). Referring to FIGS. 13 and 14, the second recess 140 may be formed by additionally etching the active region 120 in the first recess 130. Here, the active region 120 may be etched by wet etching, thereby forming the second recess 140, but aspects of the present inventive concept are not limited thereto.

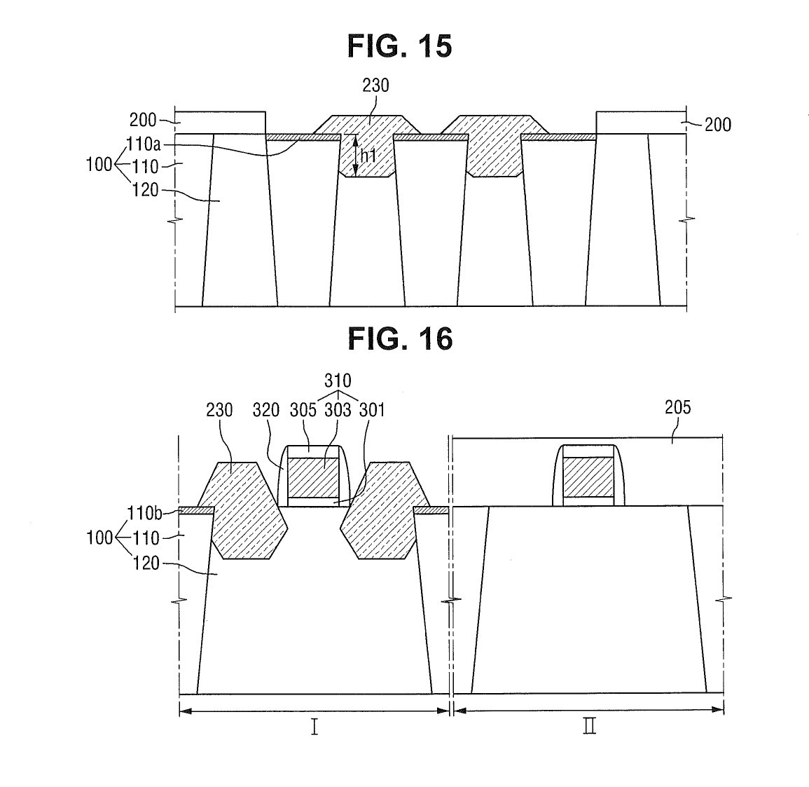

The second recess 140 may be formed in the first recess 130 and may have a sigma (Σ) shape, which is, however, illustrated only by way of example. For example, the second recess 140 may have a box shape. If the second recess 140 is formed, a stress film (230 of FIG. 15) may also be formed to be adjacent to a channel area positioned under the gate electrode structure 310, by which stress may be given to the channel area.

A depth d2 of the second recess 140 is larger than a depth (d1 of FIG. 11) of the first recess 130, and the second recess 140 has a larger internal space than the first recess 130 because the active region 120 underlying the gate electrode structure 310 and the gate spacer 320 is also etched.

Next, referring again to FIG. 1, a stress film is formed in the first recess 130 (S500). Referring to FIGS. 15 and 16, the stress film 230 may be formed by filling the first recess 130, and may be higher than the nitridated isolation regions 110a and 110b. A height of the stress film 230 may be adjusted through a subsequent planarization process. The stress film 230 may be formed through epitaxial growth.

The stress film 230 may include SiGe. If the stress film 230 includes SiGe, a compressive stress may be applied to the channel area. If the channel area has holes, that is, if the compressive stress is applied to the channel area in the PMOS, performance of transistor may be improved. Therefore, the stress film 230 may be formed in the first region I.

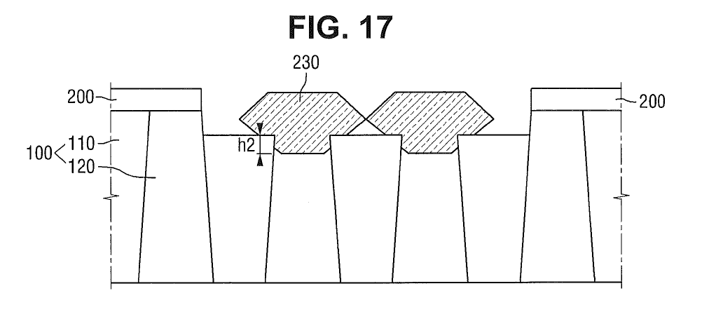

Next, effects demonstrated in a method for fabricating a semiconductor device according to an embodiment of the present inventive concept will be described with reference to FIGS. 15 and 17.

FIG. 17 illustrates effects demonstrated in a method for fabricating a semiconductor device according to an embodiment of the present inventive concept.

FIG. 17 illustrates a semiconductor device having a stress film 230 formed after forming a recess without nitridating a top surface of the isolation region 110. In FIG. 17, the isolation region 110 and the active region 120 include different materials, thereby forming the recess in the active region 120. That is to say, if etching is performed to form the recess, the etching amount of the active region 120 is larger than that of the isolation region 110 due to a difference in the etching selectivity between the isolation region 110 and the active region 120. During this process, however, since the isolation region 110 is also etched together with the active region 120, a height difference h2 between the top surface of the isolation region 110 and the top surface of the active region 120 is not so large. Therefore, in a case where the stress film 230 is formed through epitaxial growth, since an internal space of the recess is not so wide, the stress film 230 formed outside the recess may have an increased size. Eventually, a bridge may be generated between the stress films 230 to merge the CPI areas, lowering the reliability of a transistor, specifically a PMOS transistor.

Like in the fabricating method of the semiconductor device according to an embodiment of the present inventive concept, if the top surface of the isolation region 110 is nitridated, the isolation region 110 is not etched when the recess is formed in the active region 120. Thus, as shown in FIG. 15, since the height difference h1 between the top surface of the nitridated isolation region 110a and the active region 120 is larger than the height difference h2 between the top surface of the isolation region 110 and the top surface of the active region 120, an internal space of the recess is large and the stress film 230 formed outside the recess has a reduced sized. Therefore, even if the stress films 230 are formed, a bridge may not be generated between the stress films 230. That is to say, if the nitridated isolation region 110 is formed by nitridating the top surface of the isolation region 110, the reliability of the transistor can be improved.

Hereinafter, a method for fabricating a semiconductor device according to another embodiment of the present inventive concept will be described with reference to FIGS. 2 and 18 to 23.

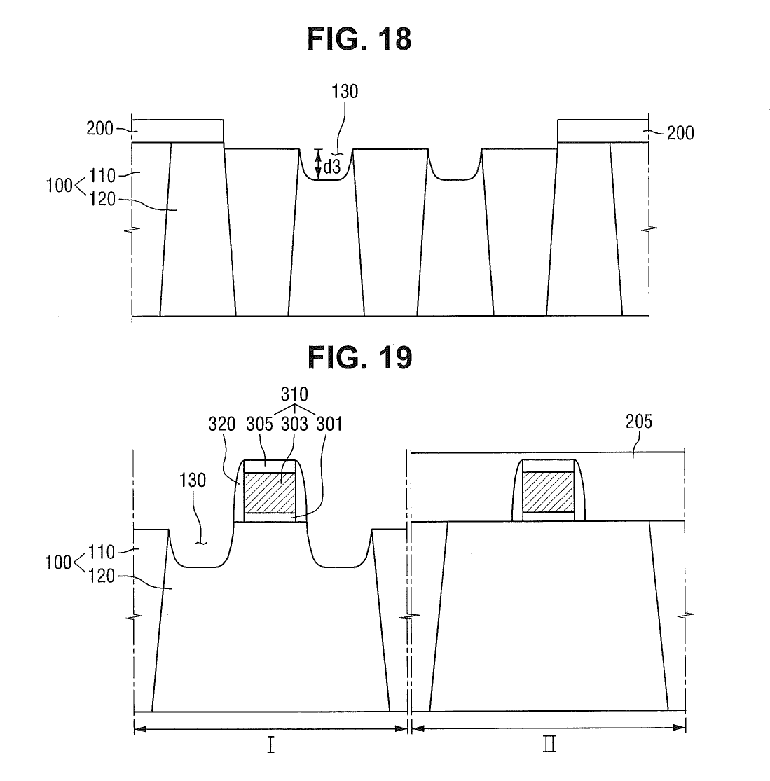

FIGS. 18 to 23 illustrate intermediate process steps for explaining a method for fabricating a semiconductor device according to another embodiment of the present inventive concept. Specifically, FIGS. 18, 20 and 22 are cross-sectional views taken along the line A-A of FIG. 2, and FIGS. 19, 21 and 23 are cross-sectional views taken along the lines B-B and C-C of FIG. 2.

Like in the method for fabricating a semiconductor device according to the previous embodiment of the present inventive concept, in the method for fabricating a semiconductor device according to another embodiment of the present inventive concept, the etch stop layer 200 is patterned on the substrate 100 having the isolation region 110 and the active region 120 to expose the isolation region 110 and the active region 120, specifically, the first region I of the active region 120, followed by performing plasma nitridation 220, thereby nitridating the top surface of the exposed isolation region 110.

Next, as shown in FIGS. 18 and 19, a first recess 130 is formed on the exposed active region 120. Unlike in the method for fabricating a semiconductor device according to the previous embodiment of the present inventive concept, in the method for fabricating a semiconductor device according to another embodiment of the present inventive concept, wet etching, instead of dry etching, is used in forming the first recess 130. In a case of using the wet etching, an etchant used in the wet etching may include HF.

When the dry etching is performed, the nitridated isolation regions 110a and 110b are not substantially etched. However, the nitridated isolation regions 110a and 110b may be etched by performing the wet etching. This is because the etching selectivity of wet etching is lower than that of dry etching. In a case where the top surfaces of the nitridated isolation regions 110a and 110b are wet etched, the etching amount of the top surfaces of the nitridated isolation regions 110a and 110b is reduced by 50% or greater, compared to a case where the top surface of the non-nitridated isolation region 110 is wet etched. For example, the amount of dry etching of the non-nitridated isolation region 110 is approximately 21 Angstroms while the amount of wet etching of the nitridated isolation regions 110a and 110b is 9 Angstroms or less.

However, even if the etching selectivity of wet etching is lower than that of dry etching, it may be high enough to prevent a bridge from being generated between the stress films 230. Therefore, the fabricating method of the semiconductor device according to the present embodiment may have the same effects as those of the fabricating method of the semiconductor device according to the previous embodiment.

Meanwhile, when the nitridated isolation regions 110a and 110b are removed, some of the isolation region 110 may be etched. However, the etching amount of the isolation region 110 may be too small to adversely affect the present inventive concept.

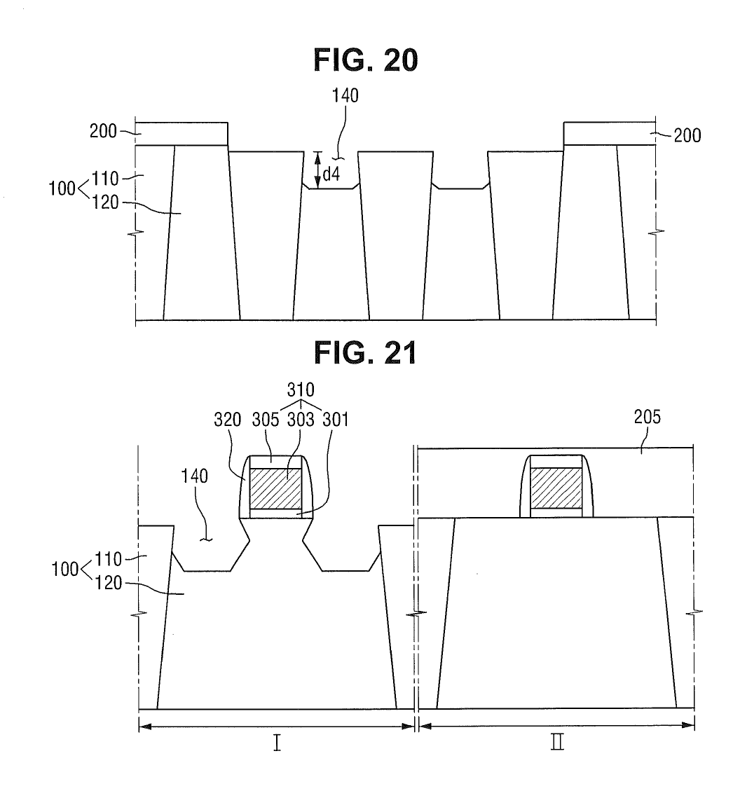

Next, referring to FIGS. 20 and 21, a second recess 140 is formed in the first recess 130. A depth d4 of the second recess 140 is larger than a depth (d3 of FIG. 18) of the first recess 130, and the second recess 140 has a larger internal space than the first recess 130. As described above, the second recess 140 may have a sigma (Σ) shape.

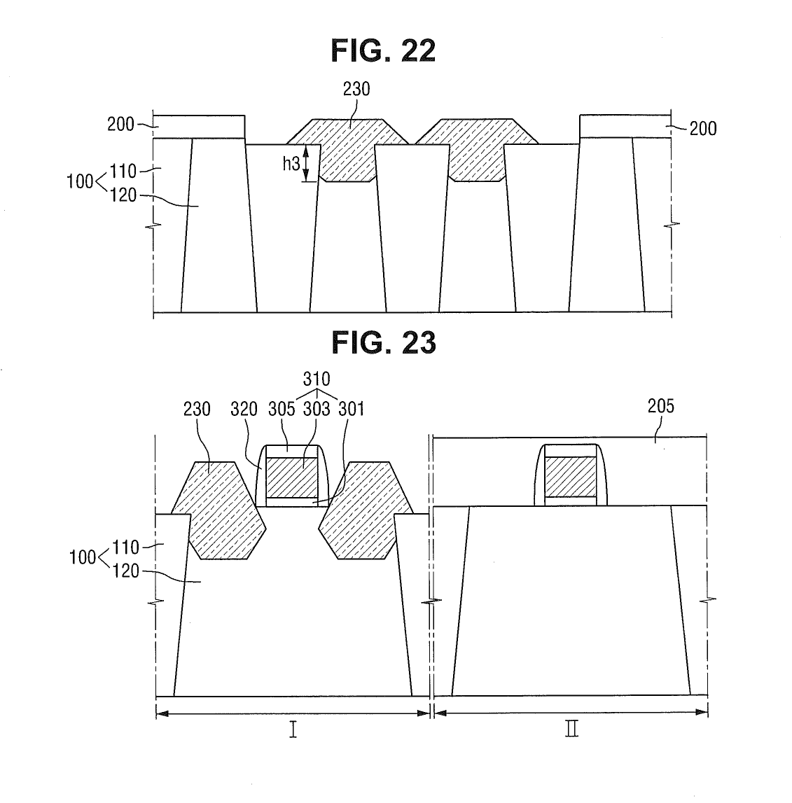

Next, referring to FIGS. 22 and 23, a stress film 230 is formed in the second recess 140 through epitaxial growth. Since the nitridated isolation regions 110a and 110b are removed, a height difference h3 between the top surface of the isolation region 110 and the top surface of the active region 120 is smaller than the height difference (h1 of FIG. 15) between the top surfaces of the isolation regions 110a and 110b and the top surface of the active region 120. However, the height difference h3 between the top surface of the isolation region 110 and the top surface of the active region 120 is larger than the height difference h2 of FIG. 17. Therefore, according to the method for fabricating a semiconductor device according to another embodiment of the present inventive concept, a bridge may not be generated between the stress films 230. Therefore, the fabricating method of the semiconductor device according to the present embodiment may have the same effects as those of the fabricating method of the semiconductor device according to the previous embodiment.

Hereinafter, a method for fabricating a semiconductor device according to still another embodiment of the present inventive concept will be described with reference to FIGS. 2 to 6 and 24 to 34.

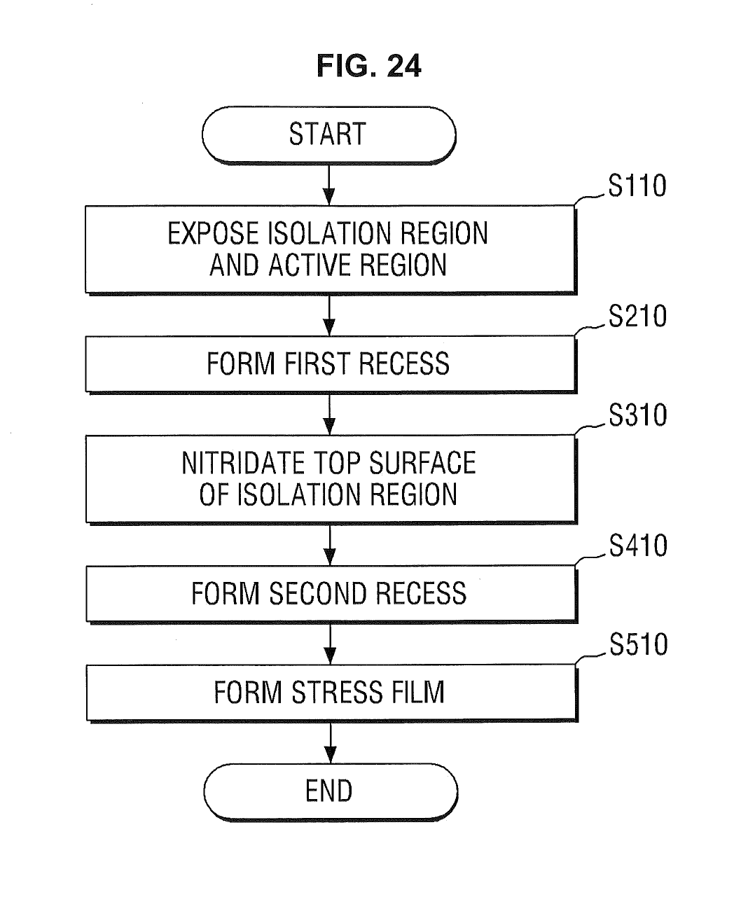

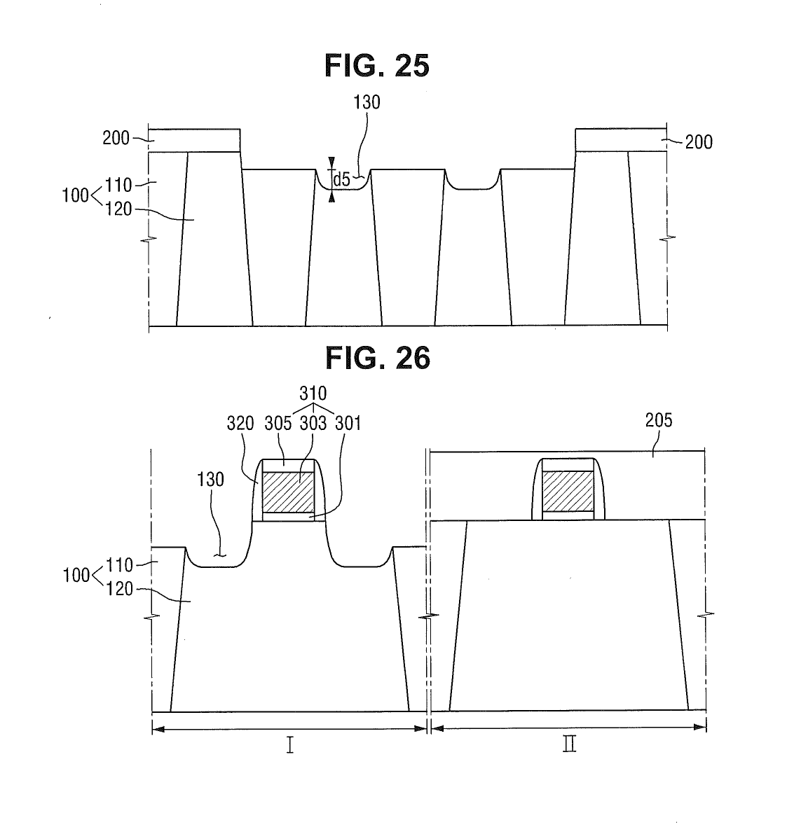

FIG. 24 is a flowchart illustrating a method for fabricating a semiconductor device according to still another embodiment of the present inventive concept, and FIGS. 25 to 34 illustrate intermediate process steps for explaining a method for fabricating a semiconductor device according to still another embodiment of the present inventive concept. Specifically, FIGS. 25, 27, 29, 31 and 33 are cross-sectional views taken along the line A-A of FIG. 2, and FIGS. 26, 28, 30, 31 and 34 are cross-sectional views taken along the lines B-B and C-C of FIG. 2.

First, referring to FIGS. 2 to 6 and 24, the etch stop layer 200 formed on the substrate 100 having the isolation region 110 and the active region 120 is patterned, thereby exposing the isolation region 110 and the active region 120 (S110). This process is the same as that of the fabricating method of the semiconductor device according to the previous embodiment.

Next, referring again to FIG. 24, the first recess 130 is formed on the exposed active region 120 (S210). Referring to FIGS. 25 and 26, unlike in the method for fabricating a semiconductor device according to the previous embodiment of the present inventive concept, in the method for fabricating a semiconductor device according to still another embodiment of the present inventive concept, the first recess 130 is formed without nitridating the top surface of the isolation region 110. Therefore, when the isolation region 110 is formed on the active region 120, the isolation region 110 is also etched. However, since the isolation region 110 and the active region 120 are formed of different materials, there is a difference in the etching selectivity between the isolation region 110 and the active region 120. Accordingly, the isolation region 110 is etched less than the active region 120. However, a depth d5 of the first recess 130 is smaller than a depth of the first recess 130 in a case of performing plasma nitridation. That is to say, d5 is smaller than d1 of FIG. 11 or d3 of FIG. 18.

For example, at least one of dry etching and wet etching may be used in forming the first recess 130.

Meanwhile, like in the method for fabricating a semiconductor device according to the previous embodiment of the present inventive concept, the first recess 130 is formed on only the first region I of the active region 120 and is not formed on the second region II of the active region 120 due to presence of the etch stop layer 205.

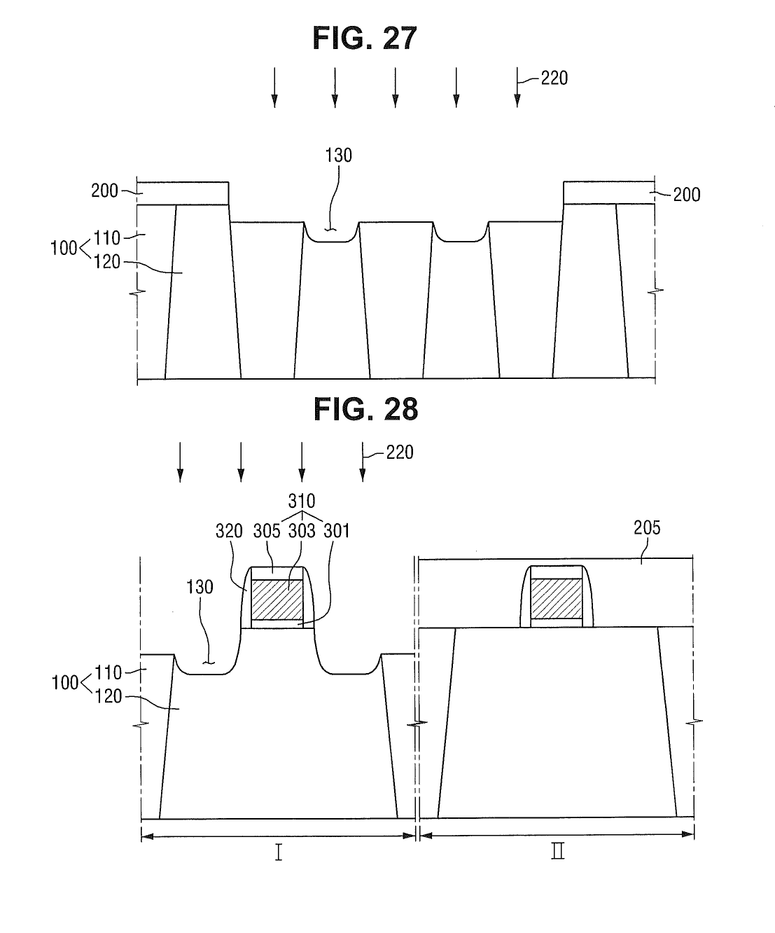

Next, referring again to FIG. 24, after forming the first recess 130, the top surface of the exposed isolation region 110 is nitridated by performing plasma nitridation (S310). As shown in FIGS. 27 and 28, plasma nitridation 220 is performed. The use of the plasma nitridation 220 allows the top surface of the exposed isolation region 110 to be uniformly nitridated to a desired thickness. When the top surface of the isolation region 110 is nitridated, the exposed active region 120 may also be nitridated.

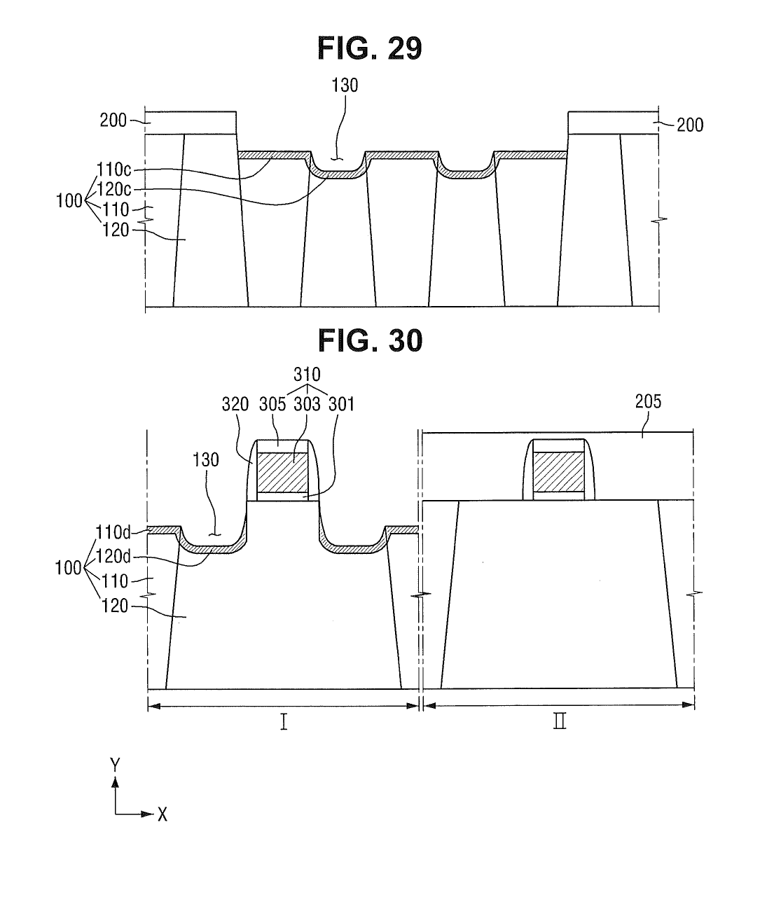

As the result of the plasma nitridation 220, as shown in FIGS. 29 and 30, the top surface of the isolation region 110 and the top surface of the first recess 130 formed in the active region 120 are nitridated to a uniform thickness. In the plasma nitridation 220, since nitridation is performed in the x-axis direction but is not performed in the x-axis direction, portions underlying the active region 120 having the gate electrode structure 310 and the gate spacer 320 is not nitridated.

As the result of the plasma nitridation 220, nitridated isolation regions 110c and 110d are formed on the exposed isolation region 110, and nitridated active regions 120c and 120d are formed on the exposed active region 120. The nitridated active region 120d is formed on the exposed first region I of the active region 120, where etch stop layers 200 and 205 are not formed.

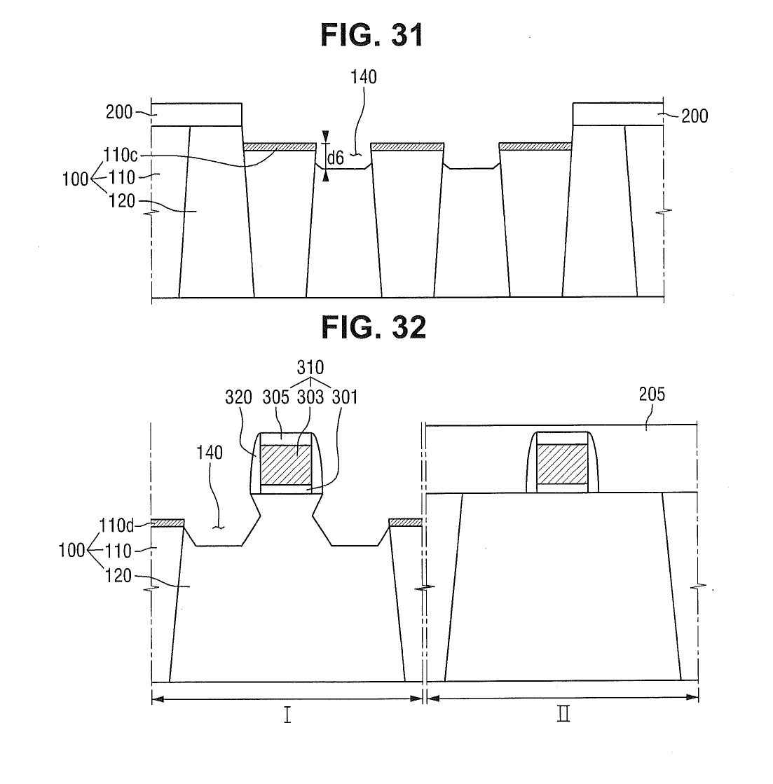

Next, referring again to FIG. 24, a second recess 140 is formed (S410). Referring to FIGS. 31 and 32, the second recess 140 is formed in the first recess 130. Here, the isolation region 110 is not etched by the nitridated isolation regions 110c and 110d.

The second recess 140 may have a sigma (Σ) shape. A depth d6 of the second recess 140 is larger than a depth (d5 of FIG. 25) of the first recess 130. Therefore, the second recess 140 has a larger volume than the first recess 130.

For example, dry etching and/or wet etching may be used in forming the second recess 140. Even if the top surface of the first recess (130 of FIG. 29) is nitridated, the nitridated active regions 120c and 120d have small thicknesses, so that the active region 120 may be etched, thereby forming the second recess 140.

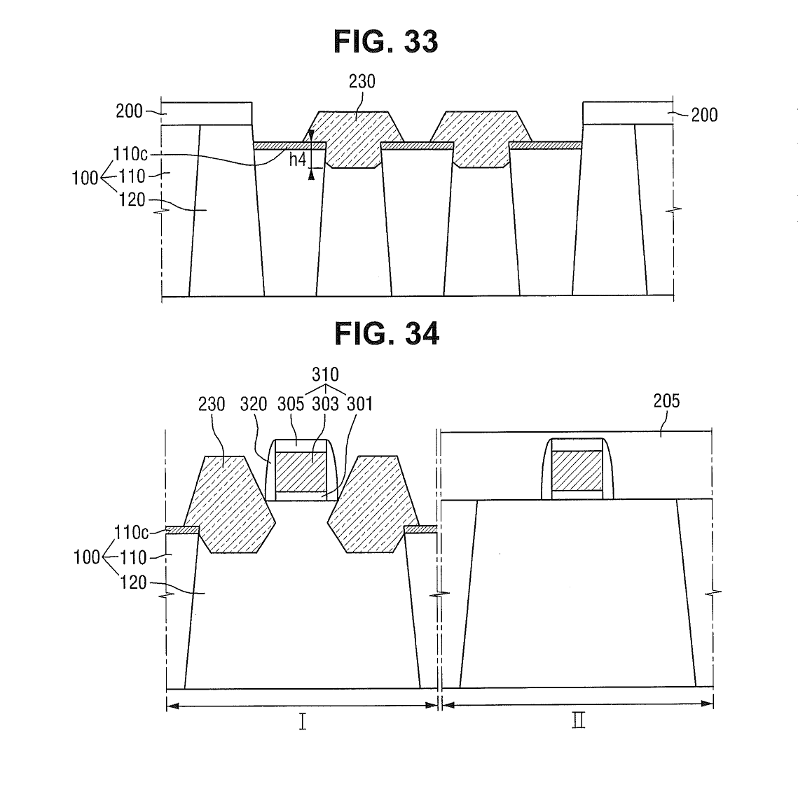

Next, referring again to FIG. 24, a stress film 230 is formed (S510). Referring to FIGS. 33 and 34, the stress film 230 may be formed in the first recess 130, that is, in the second recess 140. A top surface of the stress film 230 formed through epitaxial growth may be higher than top surfaces of the nitridated isolation regions 110c and 110d, and the stress film 230 may include SiGe.

A height difference h4 between the top surfaces of the isolation region 110c and 110d and the top surface of the active region 120 is larger than the height difference (h2 of FIG. 17) between the top surface of the non-nitridated isolation region 110 and the top surface of the active region 120, and an internal space of the second recess 140 is sufficiently wide. Therefore, in a case where the stress films 230 are formed to have the same volume, the stress film 230 formed outside the second recess 140 may have a reduced size, and a bridge is not generated between the stress films 230. Eventually, after forming the first recess 130, even if the top surface of the exposed isolation region 110 and the top surface of the exposed active region 120 are nitridated by performing plasma nitridation 220, the fabricating method of the semiconductor device according to the present embodiment may have the same effects as those of the fabricating method of the semiconductor device according to the previous embodiment.

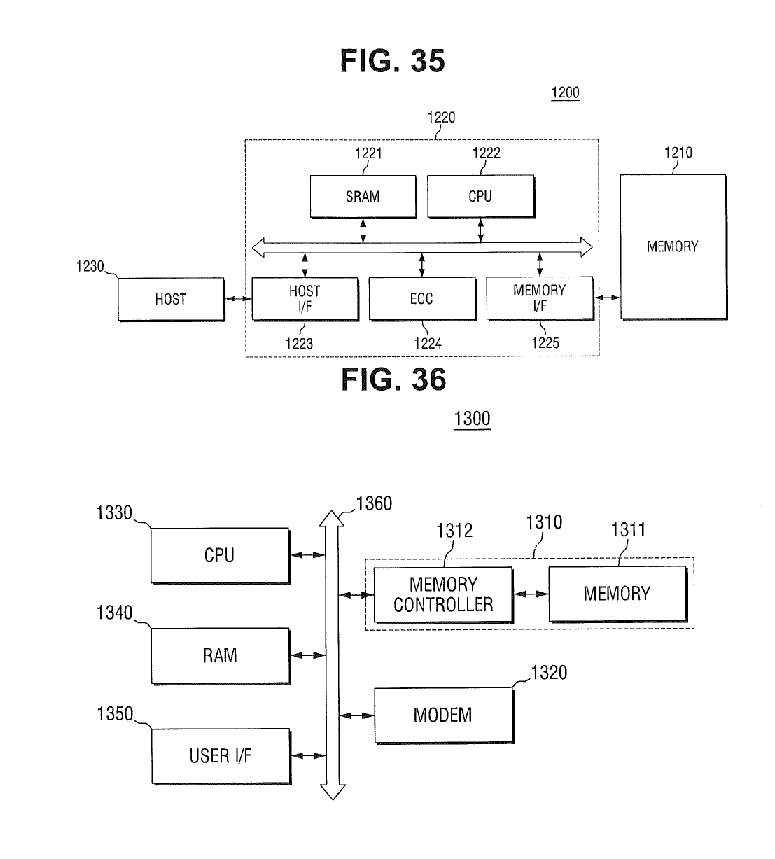

FIG. 35 is a block diagram of a memory card incorporating a semiconductor device fabricated by a fabricating method according to some embodiments of the present inventive concept.

Referring to FIG. 35, a memory 1200 incorporating a semiconductor device fabricated by a fabricating method according to some embodiments of the present inventive concept may be employed to the memory card 1200. The memory card 1200 includes a memory controller 1220 controlling the exchange of data between a host 1230 and the memory 1210. An SRAM 1221 may be used as an operational memory of a central processing unit (CPU) 1222.

A host interface (I/F) 1223 is equipped with a data communication protocol for data exchange of the host 1230 connected with the memory card 1200. An error correction code (ECC) unit 1224 may detect and correct an error bit(s) included in the data read from the memory 1210. The memory I/F 1225 may perform interfacing with the memory 100. The CPU 1222 performs general control operations to exchange data of the memory controller 1220.

FIG. 36 is a block diagram showing an information processing system (1300) using a semiconductor device fabricated by a fabricating method according to some exemplary embodiments of the present inventive concept.

Referring to FIG. 36, the information processing system 1300 may include a memory system 1310, a modem 1320, a central processing unit (CPU) 1330, a random access memory (RAM) 1340 and a user interface 1350, which are connected to a system bus 1360. The memory system 1310 may include a memory 1311 and a memory controller 1312. The memory system 1310 may be configured substantially the same as the memory card 1200 described above with respect to FIG. 35. The memory system 1310 may store data processed by the CPU 1330 or data provided from an external device. The information processing system 1300 may be applied to a memory card, a solid state disk (SSD), a camera image processor (CIS), and other various application chipsets. For example, the memory system 1310 may be configured to employ SSD. In this case, the information processing system 1300 may process large-capacity data in a stable, reliable manner.

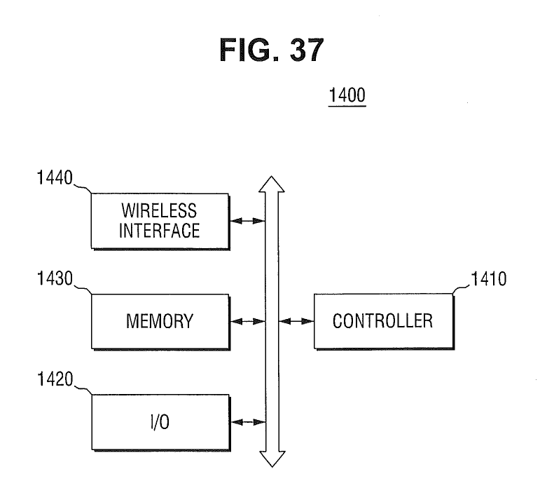

FIG. 37 is a block diagram of an electronic system including a semiconductor device according to some embodiments of the present inventive concept.

Referring to FIG. 37, the electronic system 1400 may include a semiconductor device according to some embodiments of the present inventive concept. The electronic system 1400 may be applied to a personal digital assistant (PDA), a portable computer, a web tablet, a wireless phone, a mobile phone, a digital music player, a memory card, or any type of electronic device capable of transmitting and/or receiving information in a wireless environment.

The electronic system 1400 may include a controller 1410, an input/output device (I/O) 1420, a memory 1430, and a wireless interface 1440. Here, the memory 1430 may include semiconductor devices fabricated according to various embodiments of the present inventive concept. The controller 1410 may include at least one of a microprocessor, a digital signal processor, a microcontroller, and logic devices capable of performing functions similar to those of these components. The I/O 1420 may include a keypad, a keyboard, a display, and so on. The memory 1430 may store data and/or commands processed by the controller 1410. The wireless interface 1440 may be used to transmit data to a communication network or receive data through a wireless data network. The wireless interface 1440 may include an antenna and/or a wireless transceiver. The electronic system 1400 according to some embodiments of the present inventive concept may be used in a third generation communication system such as CDMA, GSM, NADC, E-TDMA, WCDMA and CDMA2000.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed:

1. A method for fabricating a semiconductor device, the method comprising:
exposing an isolation region and an active region by patterning an etch stop layer formed on a substrate having the isolation region and the active region;
nitridating a top surface of the exposed top surface of the isolation region by performing plasma nitridation;
forming a first recess on the exposed active region; and
forming a stress film in the first recess.

2. The method of claim 1, wherein the stress film includes SiGe.

3. The method of claim 1, wherein the forming of the stress film comprises forming the stress film by epitaxial growth.

4. The method of claim 1, wherein the first recess is formed by dry etching.

5. The method of claim 4, wherein while performing the dry etching, the exposed isolation region is not substantially etched.

6. The method of claim 1, wherein the first recess is formed by wet etching.

7. The method of claim 6, wherein an etchant used in the wet etching includes HF, and an etch rate of the exposed active region is higher than that of the exposed isolation region.

8. The method of claim 1, further comprising forming a second recess in the first recess after the forming of the first recess.

9. The method of claim 8, wherein nitridating a top surface of the first region is performed after the forming of the first recess, and forming the second recess is performed after the nitridating of the top surface of the exposed isolation region.

10. The method of claim 1, wherein the active region includes a first region and a second region, and the stress film is formed in the first region.

11. The method of claim 10, wherein the first region include a PMOS region.

12. A method for fabricating a semiconductor device, the method comprising:
providing a substrate having a first region and a second region isolated by an isolation region;
forming an etch stop layer on the second region;
nitridating a top surface of the isolation region and a top surface of the first region by performing plasma nitridation;
forming a first recess in the first region; and
forming a stress film in the first recess.

13. The method of claim 12, wherein the first region includes a PMOS region, and the second region includes an NMOS region.

14. The method of claim 12, wherein nitridating the top surface of the isolation region and the top surface of the first region by performing plasma nitridation is performed after the forming of the first recess, and
forming a second recess the first recess is performed after the nitridating of the top surface of the isolation region and the top surface of the active region.

15. A method of forming a semiconductor device, the method comprising:
providing a plasma nitrided exposed top surface including an active region and an isolation region;
subjecting the exposed top surface including the active region and the isolation region to etching to form a deeper recess in the active region than in the isolation region; and
growing an unmerged epitaxial stress film in the deeper recess.

16. The method of claim 15 wherein subjecting the exposed top surface including the active region and the isolation region to etching is preceded by:
forming a first recess in the active region, wherein subjecting the exposed top surface including the active region and the isolation region to etching comprises forming a second recess in the first recess.

17. The method of claim 15 wherein subjecting the exposed top surface including the active region and the isolation region to etching is followed by:
forming a second recess in the active region, wherein subjecting the exposed top surface including the active region and the isolation region to etching comprises forming a first recess co-located where the second recess is formed.

18. The method of claim 15 wherein subjecting the exposed top surface including the active region and the isolation region to etching comprises dry-etching or wet-etching the exposed top surface.

19. The method of claim 15 wherein subjecting the exposed top surface including the active region and the isolation region to etching comprises wet etching using HF so that an etch rate of the active region is greater than that of the isolation region.

20. The method of claim 15 wherein growing an unmerged epitaxial stress film in the deeper recess comprises growing epitaxial stress films in directly adjacent deeper recesses in the active region onto the exposed top surface toward each other so that the epitaxial stress films are separated from one another.
